(19) United States
(12) Patent Application Publication
(10) Pub. No.: US 2008/0151599 A1
(43) Pub. Date: Jun. 26, 2008

(54) Semiconductor Device Including a Ferroelectric Field-Effect Transistor, and Semiconductor Integrated Circuit Device Employing Same

(75) Inventors: Daisuke Nishinohara, Kyoto-shi (JP); Masato Moriwake, Kyoto-shi (JP)

Correspondence Address: FISH & RICHARDSON P.C., P.O. BOX 1022, MINNEAPOLIS, MN, 55440-1022, US

(73) Assignee: Rohm Co., Ltd., Kyoto (JP)

(21) Appl. No.: 11/958,740

(22) Filed: Dec. 18, 2007

(30) Foreign Application Priority Data
Dec. 19, 2006 (JP) 2006-340676

(51) Int. Cl. G11C 11/22

(52) U.S. Cl. 365/145

(57) ABSTRACT

A semiconductor device has a ferroelectric field-effect transistor having a gate portion whose equivalent circuit is composed of a ferroelectric capacitor C_{F} and a paraelectric capacitor C_{P} connected in series, the ferroelectric field-effect transistor having a threshold voltage V_{TH} corresponding to a residual polarization of the ferroelectric capacitor C_{F}, and a control portion (not shown) writing a residual polarization state corresponding to a potential difference between the gate and the back gate of the ferroelectric field-effect transistor by fixing the gate potential of the ferroelectric field-effect transistor (for example, fixing it to a ground potential) and changing the back gate potential of the ferroelectric field-effect transistor (for example, switching it between +10 V and −10 V).

This application is based on Japanese Patent Application No. 2006-340676 filed on Dec. 19, 2006, the contents of which are hereby incorporated by reference.

### BACKGROUND OF THE INVENTION

1. Field of the Invention

The present invention relates to a semiconductor device including a ferroelectric field-effect transistor and to a semiconductor integrated circuit device employing such a semiconductor device.

2. Description of Related Art

A ferroelectric field-effect transistor is used, for example, in a 1Tr-type FeRAM. There has been proposed a ferroelectric field-effect transistor having a MFS structure obtained by replacing an oxidized layer of a MOS field-effect transistor with a ferroelectric layer. With this structure, however, it is difficult to achieve a good interface between the ferroelectric layer and the semiconductor bulk. It is for this reason that MFIS and MFMIS structures are usually adopted (see, for example, FIG. 3 of JP-A-2000-77986). FIG. 3 shows an example of a cross-section structure of an N-channel ferroelectric field-effect transistor having the MFMIS structure. In the ferroelectric field-effect transistor shown in FIG. 3, an insulating layer (gate oxide layer) 21 is formed on a P-type semiconductor substrate 20 in the P-channel region thereof, a lower conductive layer 22 is formed on the insulating layer (gate oxide layer) 21, a ferroelectric layer 23 is formed on the lower conductive layer 22, and an upper conductive layer 24 is formed on the ferroelectric layer 23.

Next, with reference to FIG. 4, how to write data to the ferroelectric field-effect transistor having the MFIS or MFMIS structure will be described. The ferroelectric field-effect transistor having the MFIS or MFMIS structure has a gate portion whose equivalent circuit is composed of a ferroelectric capacitor C_{F} and a paraelectric capacitor C_{P} connected in series. Writing of data to the ferroelectric field-effect transistor having the MFIS or MFMIS structure is achieved by writing a direction of polarization of the ferroelectric capacitor C_{F} by application of a voltage to the ferroelectric capacitor C_{F}. At the time of reading of data, the direction of polarization of the ferroelectric capacitor is detected as a difference in drain current by applying a predetermined gate voltage and a predetermined source-drain voltage.

In the ferroelectric field-effect transistor having the MFIS or MFMIS structure, since the equivalent circuit of the gate portion thereof is composed of the ferroelectric capacitor C_{F} and the paraelectric capacitor C_{P} connected in series, applied to the ferroelectric capacitor C_{F} is a voltage obtained by dividing a gate-back gate voltage by the ferroelectric capacitor C_{F} and the paraelectric capacitor C_{P}. As a result, writing of the direction of polarization of the ferroelectric capacitor C_{F} by application of voltage to the ferroelectric capacitor requires a very high voltage to be applied to the gate electrode. For example, a gate voltage of the order of +10 V is applied when writing data “1”, and a gate voltage of the order of −10 V is applied when writing data “0”.

This makes it necessary to provide on the gate side, in addition to a logic circuit, an additional circuit, such as a level shifter, that performs potential conversion. On the other hand, since a sufficiently low gate voltage needs to be applied so as not to affect the direction of polarization of the ferroelectric capacitor at the time of reading of data, it is necessary to feed an output of the logic circuit provided on the gate side, as it is, to the gate electrode without letting the additional circuit perform potential conversion thereon. Thus, with the conventional data writing method, a circuit configuration of a circuit provided on the gate side becomes unfavorably complicated.

### SUMMARY OF THE INVENTION

An object of the present invention is to provide a semiconductor device that includes a ferroelectric field-effect transistor and that can simplify a configuration of a circuit provided on the gate side of the ferroelectric field-effect transistor, and to provide a semiconductor integrated circuit device employing such a semiconductor device.

To achieve the above object, according to one aspect of the present invention, a semiconductor device is provided with: a ferroelectric field-effect transistor having a gate portion whose equivalent circuit is composed of a ferroelectric capacitor and a paraelectric capacitor connected in series, the ferroelectric field-effect transistor having a threshold voltage corresponding to a residual polarization of the ferroelectric capacitor; and a control portion writing, to the ferroelectric capacitor, a residual polarization state corresponding to a potential difference between the gate and the back gate of the ferroelectric field-effect transistor by fixing the gate potential of the ferroelectric field-effect transistor and changing the back gate potential of the ferroelectric field-effect transistor.

With this configuration, when performing writing, the control portion fixes the gate potential of the ferroelectric field-effect transistor and changes the back gate potential of the ferroelectric field-effect transistor. This eliminates the need to increase the gate potential of the ferroelectric field-effect transistor. As a result, in the semiconductor device of the present invention, it is not necessary to provide, on the gate side of the ferroelectric field-effect transistor, an additional circuit, such as a level shifter, that performs potential conversion. This helps simplify the circuit configuration of a circuit provided on the gate side of the ferroelectric field-effect transistor.

In the semiconductor device configured as described above, from a viewpoint of facilitating the production thereof, the ferroelectric field-effect transistor may have a MFMIS structure, and a ferroelectric layer of the ferroelectric field-effect transistor may be formed so as not to lie directly above an insulating layer of the ferroelectric field-effect transistor.

To achieve the above object, according to another aspect of the present invention, a semiconductor integrated circuit device uses a plurality of semiconductor devices configured as described above. Some examples of the semiconductor integrated circuit device of the present invention are nonvolatile memories, nonvolatile logic operation circuits, nonvolatile microprocessors, nonvolatile image processors, nonvolatile multimedia processors, and nonvolatile IP cores.

In a case where the semiconductor integrated circuit device configured as described above is provided with an N-channel ferroelectric field-effect transistor and a P-channel ferroelectric field-effect transistor, the N-channel ferroelectric field-effect transistor is isolated by a well, and the P-channel ferroelectric field-effect transistor is isolated by a well. By doing so, it is possible to individually set the back gate potentials of the ferroelectric field-effect transistors.

According to the semiconductor device of the present invention and the semiconductor integrated circuit device employing it, there is no need to increase the gate potential of the ferroelectric field-effect transistor. This eliminates the need to provide, on the gate side of the ferroelectric field-effect transistor, an additional circuit, such as a level shifter, that performs potential conversion, making it possible to simplify a circuit provided on the gate side of the ferroelectric field-effect transistor.

### BRIEF DESCRIPTION OF THE DRAWINGS

FIG. 1 is a diagram showing a data writing method of the invention.

FIG. 2 is a diagram showing an example of a cross-section structure of a ferroelectric field-effect transistor provided in a semiconductor device of the invention.

FIG. 3 is a diagram showing an example of a cross-section structure of an N-channel ferroelectric field-effect transistor having the MFMIS structure.

FIG. 4 is a diagram showing a conventional data writing method.

### DETAILED DESCRIPTION OF PREFERRED EMBODIMENTS

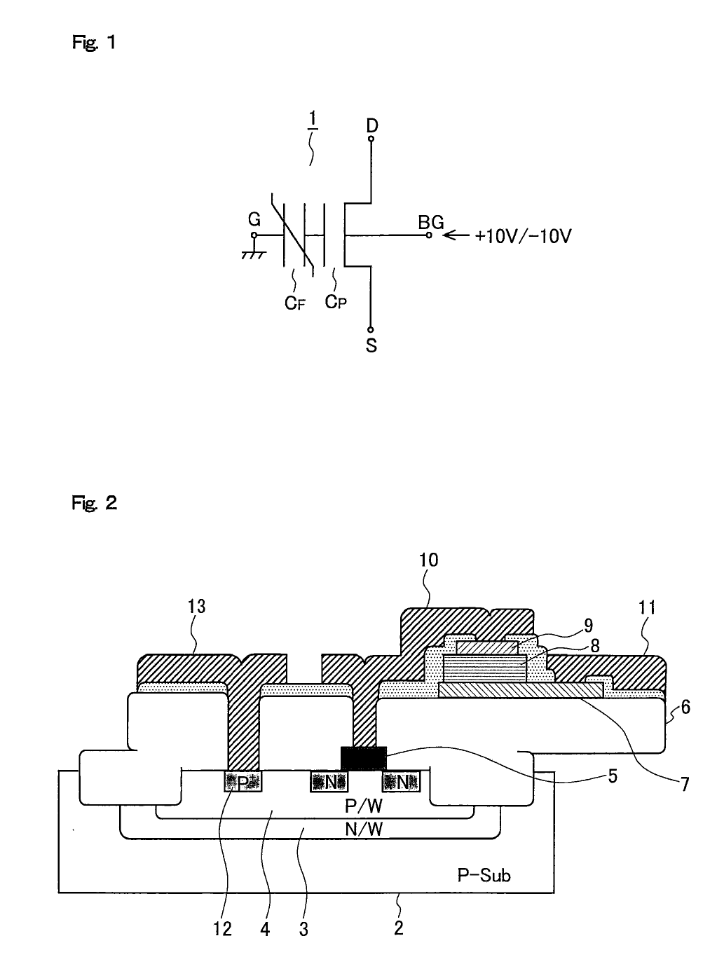

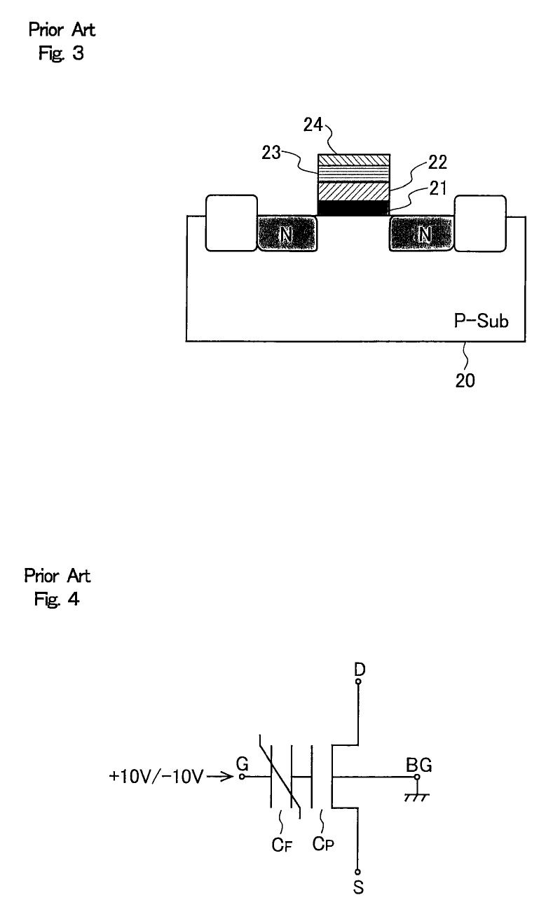

Hereinafter, with reference to the accompanying drawings, an embodiment of the present invention will be described. A semiconductor device of this embodiment includes a ferroelectric field-effect transistor 1 having a gate portion whose equivalent circuit is composed of a ferroelectric capacitor C_{F} and a paraelectric capacitor C_{P}, as shown in FIG. 1, and a control portion (not shown) that writes to the ferroelectric capacitor C_{F} a residual polarization state corresponding to a potential difference between the gate and the back gate of the ferroelectric field-effect transistor 1 in a nonvolatile manner by fixing the gate potential of the ferroelectric field-effect transistor 1 and changing the back gate potential of the ferroelectric field-effect transistor 1. For example, as shown in FIG. 1, in a case where data “1” is written, the control portion fixes the gate potential to a ground potential and sets the back gate potential to a potential of the order of −10 V; in a case where data “0” is written, it fixes the gate potential to a ground potential and sets the back gate potential to a potential of the order of +10 V.

In the semiconductor device of this embodiment, when data is written to the ferroelectric field-effect transistor 1, the gate potential of the ferroelectric field-effect transistor 1 is fixed, and the back gate potential of the ferroelectric field-effect transistor 1 is changed. This eliminates the need to increase the gate potential of the ferroelectric field-effect transistor 1. As a result, in the semiconductor device of this embodiment, there is no need to provide, on the gate side of the ferroelectric field-effect transistor 1, an additional circuit, such as a level shifter, that performs potential conversion. This contributes to simplification of the circuit configuration of a circuit provided on the gate side of the ferroelectric field-effect transistor 1. Incidentally, used as the ferroelectric field-effect transistor 1 are a ferroelectric field-effect transistor having the MFMIS structure and a ferroelectric field-effect transistor having the MFIS structure.

An example of a cross-section structure of the ferroelectric field-effect transistor 1 is shown in FIG. 2. The ferroelectric field-effect transistor shown in FIG. 2 is an N-channel ferroelectric field-effect transistor having the MFMIS structure. An N-type well 3 is formed in a P-type semiconductor substrate 2, a P-type well 4 is formed in the N-type well 3, and an insulating layer (gate oxide layer) 5 is formed on the P-type well 4 in the P-channel region thereof. A first conductive layer 7 is formed on a thermally-oxidized layer 6, a ferroelectric layer 8 is formed on the first conductive layer 7 in a left-side region thereof, and a second conductive layer 9 is formed on the ferroelectric layer 8. The top of the insulating layer (gate oxide layer) 5 and the top of the second conductive layer 9 are connected to each other via a metal contact layer 10. A gate metal contact layer 11 is connected to the top of a right-side region of the first conductive layer 7, and a back gate metal contact layer 13 is connected to the top of a heavily doped P-type impurity region 12 of the P-type well 4. The aforementioned control portion (not shown) fixes the potential of the gate metal contact layer 11, thereby fixing the gate potential of the ferroelectric field-effect transistor 1, and changes the potential of the back gate metal contact layer 13, thereby changing the back gate potential of the ferroelectric field-effect transistor 1. With the configuration shown in FIG. 2, the ferroelectric capacitor composed of the first conductive layer 7, the ferroelectric layer 8, and the second conductive layer 9 is formed so as to be away from the insulating layer (gate oxide layer) 5, instead of forming it directly on the insulating layer (gate oxide layer) 5. This makes it easy to obtain a ferroelectric layer having stable properties, and hence produce a ferroelectric field-effect transistor itself.

A semiconductor integrated circuit device of this embodiment is built with a plurality of above-described semiconductor devices of this embodiment.

In a case where the semiconductor integrated circuit device of this embodiment uses both a semiconductor device of this embodiment including an N-channel ferroelectric field-effect transistor 1 and a semiconductor device of this embodiment including a P-channel ferroelectric field-effect transistor 1, the ferroelectric field-effect transistors are each isolated by a well. For example, in a case where a P-type semiconductor substrate is used, the ferroelectric field-effect transistors are each isolated by an N well (see FIG. 2). This makes it possible to individually set the back gate potentials of the ferroelectric field-effect transistors.

On the other hand, in a case where the semiconductor integrated circuit device of this embodiment uses only one of a semiconductor device of this embodiment including an N-channel ferroelectric field-effect transistor 1 and a semiconductor device of this embodiment including a P-channel ferroelectric field-effect transistor 1, it is possible to individually set the back gate potentials of the ferroelectric field-effect transistors without using a well. In a case where only a semiconductor device of this embodiment including an N-channel ferroelectric field-effect transistor 1 is used, it is simply necessary to use an N-type semiconductor substrate. On the other hand, in a case where only a semiconductor device of this embodiment including a P-channel ferroelectric field-effect transistor 1 is used, it is simply necessary to use a P-type semiconductor substrate.

The semiconductor integrated circuit device of this embodiment can be applied, for example, to a 1Tr-type FeRAM that stores data “0” and “1” according to the direction of polarization written to the ferroelectric capacitor of the ferroelectric field-effect transistor 1. In addition, since the ferroelectric field-effect transistor 1 has a threshold voltage corresponding to a residual polarization of the ferroelectric capacitor, by using the semiconductor integrated circuit device of this embodiment, it is possible to realize a nonvolatile multivalued memory that stores data according to the amount of residual polarization written to the ferroelectric capacitor of the ferroelectric field-effect transistor 1, and, when reading data thus stored, detects the amount of residual polarization of the ferroelectric capacitor as a difference in threshold voltage.

The semiconductor integrated circuit device of this embodiment can be applied not only to nonvolatile memories but also to nonvolatile logic operation circuits, nonvolatile microprocessors, nonvolatile image processors, nonvolatile multimedia processors, nonvolatile IP cores, and the like.

What is claimed is:

1. A semiconductor device, comprising:
a ferroelectric field-effect transistor having a gate portion whose equivalent circuit is composed of a ferroelectric capacitor and a paraelectric capacitor connected in series, the ferroelectric field-effect transistor having a threshold voltage corresponding to a residual polarization of the ferroelectric capacitor; and
a control portion writing, to the ferroelectric capacitor, a residual polarization state corresponding to a potential difference between a gate and a back gate of the ferroelectric field-effect transistor by fixing a gate potential of the ferroelectric field-effect transistor and changing a back gate potential of the ferroelectric field-effect transistor.

2. The semiconductor device of claim 1,
wherein the ferroelectric field-effect transistor has a MFMIS structure,
wherein a ferroelectric layer of the ferroelectric field-effect transistor is formed so as not to lie directly above an insulating layer of the ferroelectric field-effect transistor.

3. A semiconductor integrated circuit device, wherein
the semiconductor integrated circuit device uses a plurality of semiconductor devices, each comprising:
a ferroelectric field-effect transistor having a gate portion whose equivalent circuit is composed of a ferroelectric capacitor and a paraelectric capacitor connected in series, the ferroelectric field-effect transistor having a threshold voltage corresponding to a residual polarization of the ferroelectric capacitor; and
a control portion writing, to the ferroelectric capacitor, a residual polarization state corresponding to a potential difference between a gate and a back gate of the ferroelectric field-effect transistor by fixing a gate potential of the ferroelectric field-effect transistor and changing a back gate potential of the ferroelectric field-effect transistor.

4. The semiconductor integrated circuit device of claim 3,
wherein the ferroelectric field-effect transistor has a MFMIS structure,
wherein a ferroelectric layer of the ferroelectric field-effect transistor is formed so as not to lie directly above an insulating layer of the ferroelectric field-effect transistor.

5. The semiconductor integrated circuit device of claim 3,
wherein an N-channel ferroelectric field-effect transistor and a P-channel ferroelectric field-effect transistor are provided,
wherein the N-channel ferroelectric field-effect transistor is isolated by a well,
wherein the P-channel ferroelectric field-effect transistor is isolated by a well.

6. The semiconductor integrated circuit device of claim 4,
wherein an N-channel ferroelectric field-effect transistor and a P-channel ferroelectric field-effect transistor are provided,
wherein the N-channel ferroelectric field-effect transistor is isolated by a well,
wherein the P-channel ferroelectric field-effect transistor is isolated by a well.
